(19) United States
(12) Patent Application Publication
(10) Pub. No.: US 2012/0305739 A1
(43) Pub. Date: Dec. 6, 2012

(54) ELECTRONIC DEVICE HOLDER

(75) Inventor: Po-Chin HUANG, Taipei City (TW)

(73) Assignee: OXERER TECHNOLOGIES CO., LTD., Taipei City (TW)

(21) Appl. No.: 13/484,611

(22) Filed: May 31, 2012

(30) Foreign Application Priority Data
May 31, 2011 (TW) 201120198646.7

(51) Int. Cl. H05K 7/00

(52) U.S. Cl. 248/559; 248/397

(57) ABSTRACT

An electronic device holder is revealed. The electronic device holder includes a main body, an adjustment member, a fixing part and at least one stopper. The main body consists of a supporting part and a blocking part. An electronic device is arranged at the blocking part while the supporting part holds the electronic device and the stopper is against the electronic device. One end of the adjustment member is fixed on the supporting part and the other end thereof is attached to the fixing part. An angle between the supporting part and the blocking part is adjusted by the adjustment member and the fixing part. Thus the mounting angle of the electronic device meets users' needs. The angle between the supporting part and the blocking part is changed along with the position of the adjustment member attached to the fixing part.

### BACKGROUND OF THE INVENTION

1. Field of the Invention

The present invention relates to a holder, especially to an electronic device holder supporting electronic devices and allowing the electronic device placed at an angle required.

2. Descriptions of Related Art

The fast development of modern technologies and higher requirements of our life qualities, more and more electronic devices have been invented. In order to achieve maximum effect, different kinds of portable and hand-held electronics have been produced. The most common hand-held electronics include smart phones, personal digital assistant, mobile game consoles, tablet personal computers, etc. Most of users put the portable electronic device into a protection cover so as to prevent damages to the device. However, the protective cover is only used to protect the portable electronics. While in use, the user still needs to hold the electronic in his hand(s). After a long run, this causes fatigue and stress to the user.

The protective covers with supporting function available on the market almost all include a supporting structure for holding the electronic device. In some of them, the supporting structure is unable to be adjusted. Some supporting structures can adjust the mounting angle of the electronic device but can only be adjusted to a certain number of angles. Users are unable to select the mounting angle they need.

Thus there is a need to provide a novel electronic device holder by which users can adjust the mounting angle of the electronic device according to their requirements.

### SUMMARY OF THE INVENTION

Therefore it is a primary object of the present invention to provide an electronic device holder that supports electronic devices for convenience of users.

It is another object of the present invention to provide an electronic device whose mounting angle is adjustable so as to meet users' requirements.

In order to achieve the above objects, an electronic device holder according to the present invention includes a main body, an adjustment member, a fixing part and at least one stopper. The fixing part is arranged at the main body. The main body consists of a supporting part and a blocking part. The blocking part is for mounting an electronic device and the supporting part supports the electronic device. The adjust member is used to change the angle between the supporting part and the blocking part. One end of the adjustment member is fixed on the supporting part while the other end thereof is attached to the fixing part so as to fix the angle between the supporting part and the blocking part. The stopper is disposed on the blocking part and is against electronic device.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective view of an embodiment according to the present invention;

FIG. 2 is a side view of an embodiment in use according to the present invention;

FIG. 3 is a side view of another embodiment in use according to the present invention;

FIG. 4 is a perspective view of a further embodiment according to the present invention;

FIG. 5 is a side view of a further embodiment in use according to the present invention;

FIG. 6 is a side view of a further embodiment in use according to the present invention;

FIG. 7 is a side view of a further embodiment in use according to the present invention; and

FIG. 8 is a partial cross sectional view of a further embodiment according to the present invention;

FIG. 9 is a perspective view of a further embodiment according to the present invention;

FIG. 10 is a side view of a further embodiment in use according to the present invention; and

FIG. 11 is a partial cross sectional view of a further embodiment according to the present invention.

### DETAILED DESCRIPTION OF THE PREFERRED EMBODIMENT

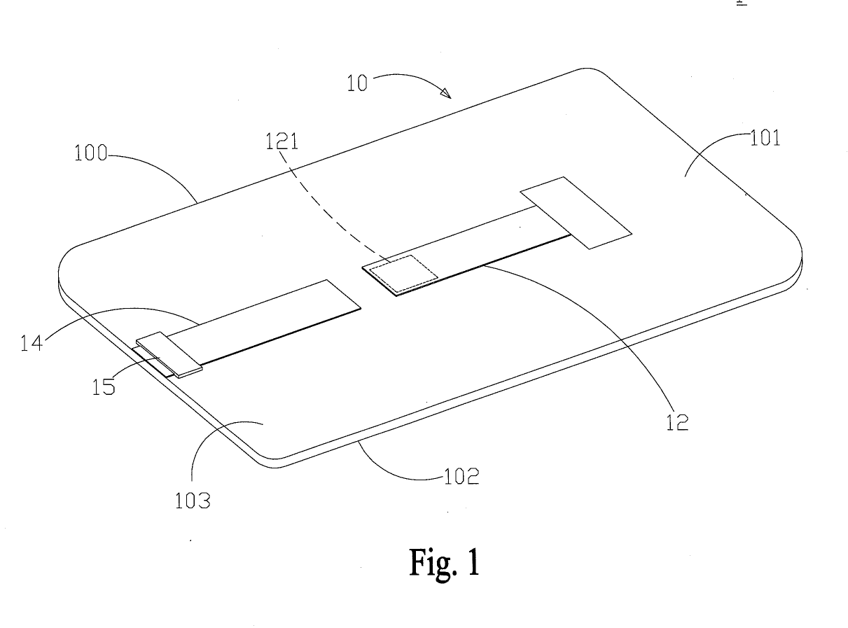

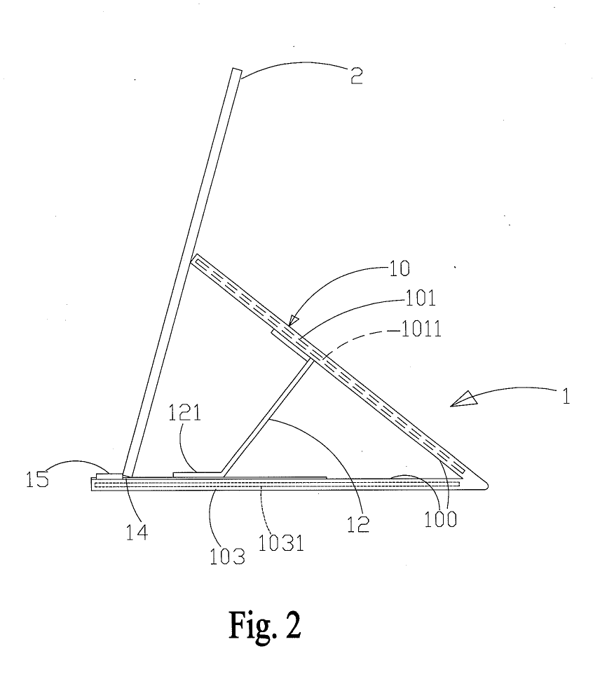

Refer to FIG. 1 and FIG. 2, an electronic device holder 1 of the present invention includes a main body 10, an adjustment member 12, a fixing part 14 and at least one stopper 15. The main body 10 consists of a supporting part 101 and a blocking part 103, respectively arranged at each of two ends of the main body 10. In this embodiment, one end of the adjustment member 12 is fixed on the supporting part 101 and is located on a first surface 100 of the main body 10. The fixing part 14 is also arranged at the first surface 100 of the main body 10. There is only one stopper 15 in this embodiment. The stopper 15 is disposed on the blocking part 103 and is located on the first surface 100 of the main body 10.

While setting an electronic device 2 on the electronic device holder 1, an angle between the supporting part 101 and the blocking part 103 is adjusted firstly. Then place the electronic device 2 onto the blocking part 103. The supporting part 101 supports the electronic device 2 while the stopper 15 is leaning against the bottom of the electronic device 2. Thus there is a certain angle (use angle) between the electronic device 2 and the horizon while in use and the electronic device 2 is fastened firmly to the electronic device holder 1, without falling off. When users intend to adjust the position of the electronic device 2, only the angle between the supporting part 101 and the blocking part 103 is adjusted. The electronic device 2 is a portable electronic such as a tablet personal computer, a personal digital assistant or a smart phone. In this embodiment, the electronic device 2 is a tablet personal computer.

The main body 10 is made from hard material or soft materials such as synthetic leather, general leather. The supporting part 101 is further arranged with a support 1011 therein. The support 1011 is a plate, rack, or others that increases strength and flexibility of the supporting part 101 to prevent the supporting part 101 from collapsing. Similarly, the blocking part 103 is disposed with a bearing part 1031 for increasing strength thereof and further improving stability of the blocking part 103 loaded with the electronic device 2.

The angle between the supporting part 101 and the blocking part 103 is mainly adjusted by the adjustment member 12 and the fixing part 14. The adjustment member 12 includes a connection part 121 on one end thereof and the connection part 121 is attached to and connected with the fixing part 14. In this embodiment, the adjustment member 12 is a flexible belt. The connection part 121 is a loop/hook component of a touch fastener (Velcro) while the fixing part 14 is a hook/loop component of the touch fastener. The above embodiment only shows a connection way between the connection part 121 and the fixing part 14. The connection part 121 and the fixing part 14 can be connected to each other by buttons and slots, locking hooks and locking slots, male connectors and female connectors engaged with each other. The adjustment member 12 can also be a flexible cord or a hard wire.

When the main body 10 is applied with an external force, an angle is created between the supporting part 101 and the blocking part 103. Without the external force, the main body 10 is automatically expanded into a flat sheet. Thus the adjustment member 12 and the fixing part 14 of the main body 10 are required and are used to fix the angle between the supporting part 101 and the blocking part 103. In this embodiment of the electronic device holder 1, the angle between the supporting part 101 and the blocking part 103 is adjusted according to the position of the connection part 121 attached to the fixing part 14. For example, when the position of the connection part 121 attached to the fixing part 14 is closer to the supporting part 101, the angle between the supporting part 101 and the blocking part 103 is larger. When the position of the connection part 121 attached to the fixing part 14 is getting away from the supporting part 101, the angle between the supporting part 101 and the blocking part 103 is getting smaller.

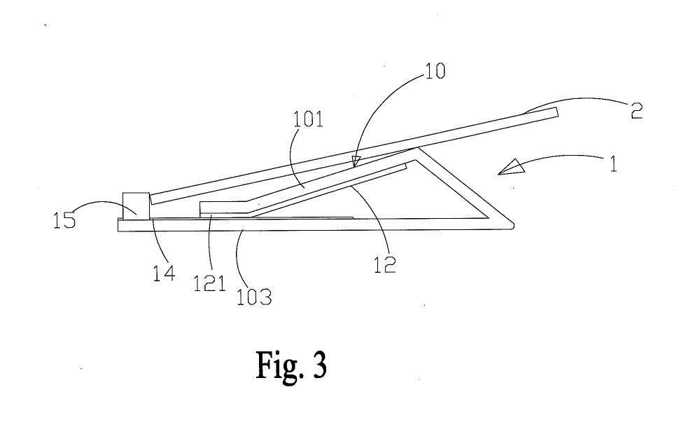

Refer to FIG. 3, another embodiment is revealed. In the above embodiment, the adjustment member 12 is a belt while the adjustment member 12 is a loop component of a touch fastener (Velcro) in this embodiment. A fixing part 14 corresponding to the adjustment member 12 is a hook component of the touch fastener in this embodiment. A connection part 121 of the adjustment member 12 is arranged at the edge of a supporting part 101. When the connection part 121 is attached to the fixing part 14, a supporting part 101 is rotated in relation to a blocking part 103 to cover a part of the blocking part 103 so as to form a certain angle between the supporting part 101 and the blocking part 103. Then the electronic device 2 is placed on the electronic device holder 1, supported by the supporting part 101 and the bottom of the electronic device 2 is stopped by a stopper 15. Thus the use angle of the electronic device 2 matches requirements of users and the electronic device holder 1 prevents the electronic device 2 from being dropped. Besides the touch fastener, the adjustment member 12 and the fixing part 14 can be magnets, buttons and slots, locking hooks and locking slots or others that are attached to each other.

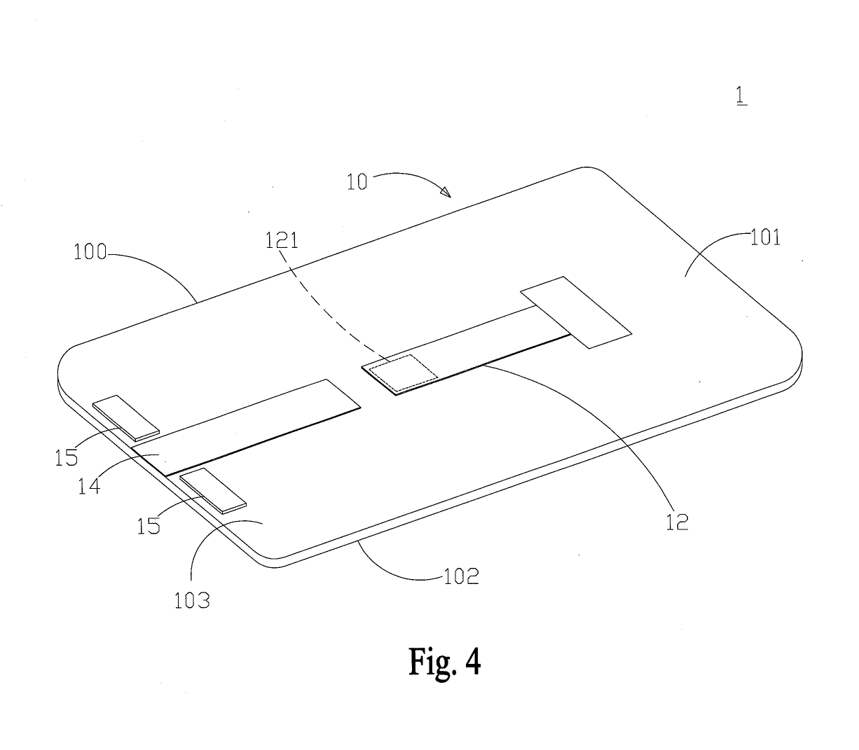

Refer to FIG. 4, a further embodiment is disclosed. As shown in figure, there is only one stopper 15 in the first embodiment. In this embodiment, there are two stoppers 15 arranged at the blocking part 103 and leaning against the bottom of the electronic device 2 so as to prevent the electronic device 2 being separated from the electronic device holder 1.

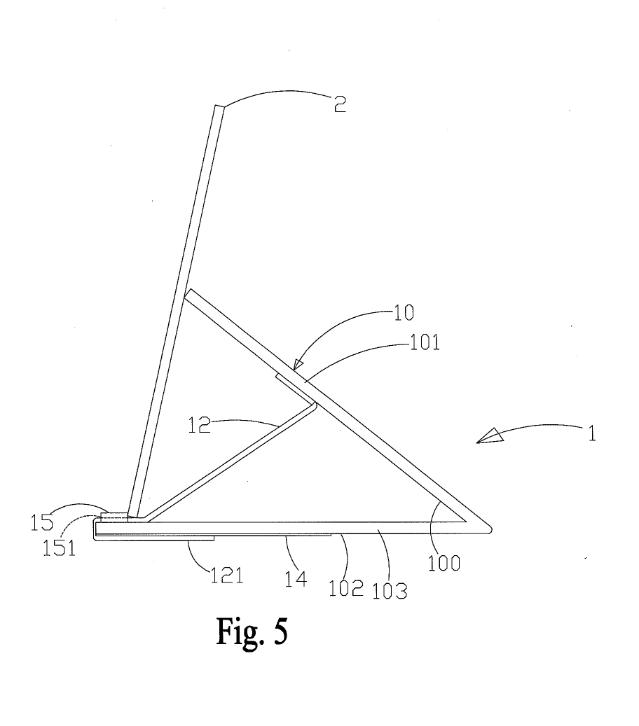

Refer to FIG. 5, this figure shows a fourth embodiment of the present invention in use. The difference between this embodiment and the first embodiment is in that the fixing part 14 of this embodiment is disposed on a second surface 102 and the connection part 121 of the adjustment member 12 is wound from the first surface 100 of the main body 10 to the second surface 102. Then the connection part 121 is attached to and connected with the fixing part 14 on the second surface 102. The angle between the supporting part 101 and the blocking part 103 is adjusted according to the position of the connection part 121 attached to and connected with the fixing part 14. For example, when the position of the connection part 121 attached to the fixing part 14 is getting closer to the supporting part 101, the angle between the supporting part 101 and the blocking part 103 is smaller. When the position of the connection part 121 attached to the fixing part 14 is getting far away from the supporting part 101, the angle between the supporting part 101 and the blocking part 103 is larger.

In this embodiment, the stopper 15 is disposed on the blocking part 103 and is located on the adjustment member 12. In order to prevent the movement of the adjustment member 12 from being affected, the stopper 15 is mounted with an though hole 151 allowing the adjustment member 12 to pass through. The adjustment member 12 passed through the though hole 151 is movable for adjustment.

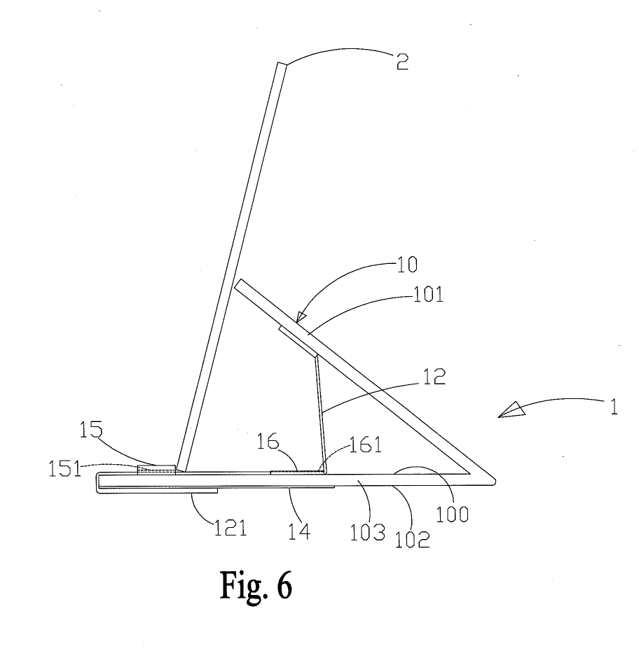

Refer to FIG. 6, a further embodiment in use is revealed. As shown in the figure, the adjustment member 12 needs to cross over the blocking part 103 because one end of the adjustment member 12 is attached to the fixing part 14. This has negative effect on the arrangement of the electronic device 2. In order to enable the electronic device 2 to be placed on the blocking part 103 of the main body stably, without being affected by the adjustment member 12, this embodiment of the electronic device holder 1 further includes a limit part 16 arranged at the first surface 100 of the main body 10. The limit part 16 includes an though hole 16 allowing the adjustment member 12 to pass through. The adjustment member 12 passed through the though hole 161 is limited by the limit part 16, located between the limit part 16 and the stopper 15 and attached to the first surface 100 of the main body 10 tightly. Thus the electronic device 2 is arranged on the blocking part 103 firmly and smoothly, without being affected by the adjustment member 12.

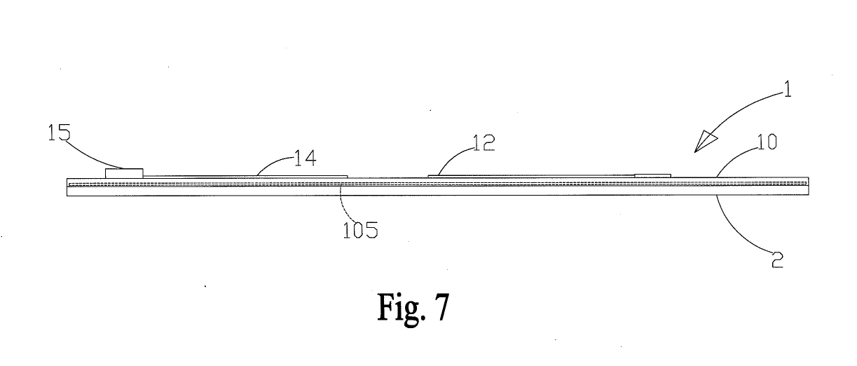

Refer to FIG. 7, a further embodiment in use is disclosed. As shown in figure, the above embodiments show the electronic device 2 in use. This embodiment is for convenience of carrying the electronic device 2 and storage. In this embodiment, an attaching layer 105 is mounted inside a main body 10 or arranged at the surface of the main body 10. In the figure, the attaching layer 105 is mounted in the main body 10 and an electronic device 2 is attached to the attaching layer 105. Thus the electronic device holder 1 and the electronic device 2 are carried conveniently at the same time. The embodiment provides the ease of carrying and protection for electronic devices. The attaching layer 105 is formed by a plurality of magnets, an electrostatic layer, a reusable attaching layer or a layer made from other materials with attaching properties.

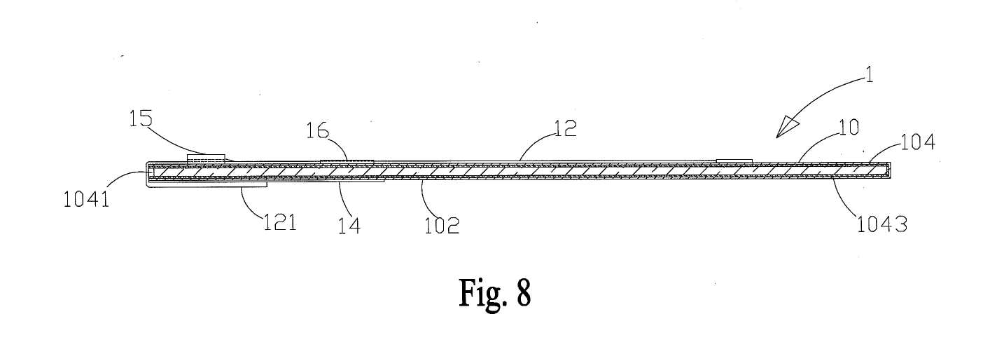

Refer to FIG. 8, a partial cross sectional view of a further embodiment is revealed. This embodiment provides another way for storage of an electronic device 2. A main body 10 of this embodiment includes a receiving part 104 with an opening 1041. The electronic device 2 is received into the receiving part 104 through the opening 1041. Thus the electronic device holder 1 and the electronic device 2 can be carried at the same time. Moreover, the electronic device 2 is protected by the electronic device holder 1. In order to prevent the electronic device 2 from falling out through the opening 1041, one end of an adjustment member 12 is over the opening 1041 to be arranged at a fixing part 14 on a second surface 102 of the main body 10. Thus the electronic device 2 will not fall out of the electronic device holder 1. The electronic device holder 1 further includes a vibration absorbing layer 1043 mounted in the receiving part 104 so as to avoid damages of the electronic device 2 caused by vibrations while being carried by users.

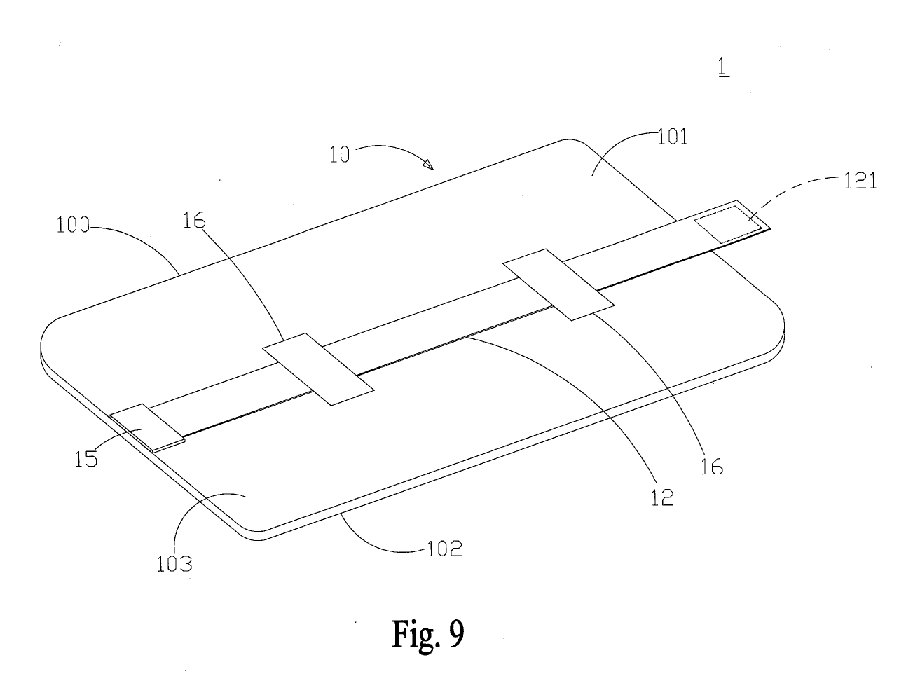

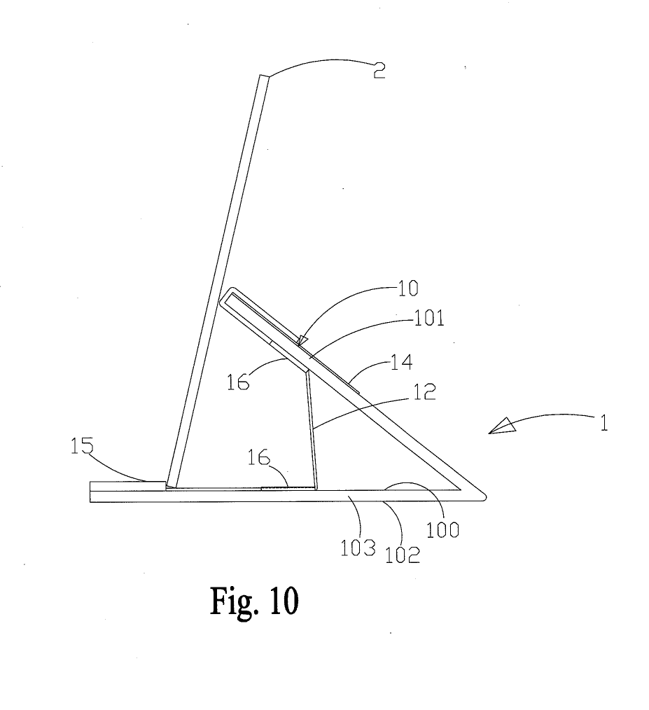

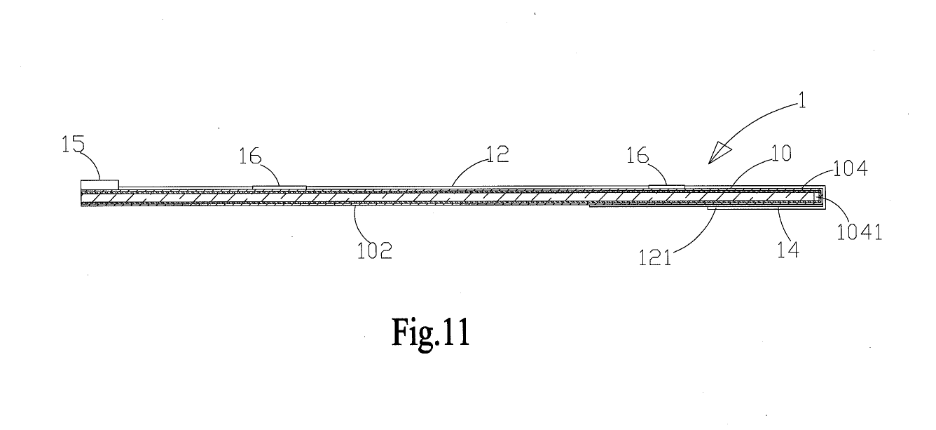

Refer to FIG. 9, FIG. 10 and FIG. 11, a further embodiment is revealed. As show in figure, in the above embodiment, one end of the adjustment member 12 is fixed on the supporting part 101 of the main body 10. The difference between this embodiment and the above one is in that one end of a adjustment member 12 is fixed on a blocking part 103 of a main body 10 while the other end of the adjustment member 12 is disposed on a supporting part 101 of the main body 10 so as to adjust an angle between the supporting part 101 and the blocking part 103. A fixing part 14 is arranged at the supporting part 101 of the main body 101, allowing a connection part 121 of the adjustment member 12 set thereon. In this embodiment, the fixing part 14 is on a second surface 102 of the main body 10. An opening 1041 of a receiving part 104 of the main body 10 is located on one side of the supporting part 101. Thus an electronic device 2 is mounted in the receiving part 104, one end of the adjustment member 12 can cross over the opening 1041 to be disposed on the fixing part 14 of the second surface 102 for preventing the electronic device 2 from falling out of the receiving part 104.

The main body 10 in this embodiment is disposed with two limit parts 16. One limit part 16 is set on the blocking part 103 while the other limit part 16 is disposed on the supporting part 101. The adjustment member 12 passes through the two limit parts 16 so that the adjustment member 12 is attached to a first surface 100 of the main body 10 more flat and smoothly. Thus the disposition of the electronic device 2 will not be affected by the adjustment member 12. Moreover, a stopper 15 is arranged at one end of the adjustment member 12 fixed on the blocking part 103 and is used to against the electronic device 2 for preventing the electronic device 2 from falling out of the blocking part 103. Moreover, it is not necessary to arrange the stopper 15 on the adjustment member 12.

In summary, the present invention provides an electronic device holder for supporting electronic devices. The electronic device holder includes the adjustment member and the fixing part so as to adjust the angle between the supporting part and the blocking part for adjustment of the mounting angle of the electronic device. The angle between the supporting part and the blocking part is adjusted according to the position of the adjustment member attached to the fixing part. The electronic device holder is used to mount electronic devices for protection and convenience of carrying.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. An electronic device holder comprising:
a main body including a blocking part for mounting an electronic device and a supporting part for support the electronic device;
an adjustment member used for adjusting an angle between the supporting part and the blocking part, and having one end thereof fixed on the supporting part;
a fixing part disposed on the main body; the other end of the adjustment member is attached to the fixing part so as to fix the angle between the supporting part and the blocking part; and
at least one stopper arranged at the blocking part and against the electronic device.

2. The device as claimed in claim 1, wherein the supporting part includes a support.

3. The device as claimed in claim 1, wherein the blocking part includes a bearing part.

4. The device as claimed in claim 1, wherein the adjustment member includes a connection part that is attached to the fixing part.

5. The device as claimed in claim 1, wherein the electronic device holder further includes:
a limit part disposed on the main body; the adjustment member passes through the limit part.

6. The device as claimed in claim 5, wherein the limit part includes an though hole and the adjustment member is passed through the though hole.

7. The device as claimed in claim 1, wherein the stopper is arranged with an though hole and is disposed on the main body; the adjustment member is passed through the though hole of the stopper.

8. The device as claimed in claim 1, wherein the main body includes a receiving part having an opening for receiving the electronic device.

9. The device as claimed in claim 8, wherein a vibration absorbing layer is mounted in the receiving part; the vibration absorbing layer covers the electronic device.

10. The device as claimed in claim 1, wherein the main body includes an attaching layer to which the electronic device attaches.

11. An electronic device holder comprising:
a main body including a blocking part for mounting an electronic device and a supporting part for support the electronic device;
an adjustment member used for adjusting an angle between the supporting part and the blocking part, and having one end thereof fixed on the blocking part;
a fixing part disposed on the main body; the other end of the adjustment member is attached to the fixing part so as to fix the angle between the supporting part and the blocking part; and
at least one stopper arranged at the blocking part and against the electronic device.

12. The device as claimed in claim 11, wherein the supporting part includes a support.

13. The device as claimed in claim 11, wherein the blocking part includes a bearing part.

14. The device as claimed in claim 11, wherein the adjustment member includes a connection part that is attached to the fixing part.

15. The device as claimed in claim 11, wherein the electronic device holder further includes: a limit part disposed on the main body; the adjustment member passes through the limit part.

16. The device as claimed in claim 15, wherein the limit part includes an though hole and the adjustment member is passed through the though hole.

17. The device as claimed in claim 11, wherein the main body includes a receiving part having an opening for receiving the electronic device.

18. The device as claimed in claim 17, wherein a vibration absorbing layer is mounted in the receiving part; the vibration absorbing layer covers the electronic device.

19. The device as claimed in claim 11, wherein the main body includes an attaching layer to which the electronic device attaches.
